(19) United States
(12) Patent Application Publication
(10) Pub. No.: US 2020/0225581 A1
(43) Pub. Date: Jul. 16, 2020

(54) PHOTOSENSITIVE RESIN COMPOSITION, OPTICAL FILM, AND METHOD OF PRODUCING OPTICAL FILM

(71) Applicant: eChem Solutions Corp., Taoyuan (TW)

(72) Inventors: Jui-Yu Hsu, Taoyuan (TW); Chia-Hao Lou, Taoyuan (TW); Chen-Wen Chiu, Taoyuan (TW)

(73) Assignee: eChem Solutions Corp., Taoyuan (TW)

(21) Appl. No.: 16/741,682

(22) Filed: Jan. 13, 2020

(30) Foreign Application Priority Data
Jan. 15, 2019 (TW) 108101438

(51) Int. Cl. G03F 7/038; G03F 7/16; G03F 7/004; C08F 20/30; C08F 20/32; G02B 1/04

(52) U.S. Cl. CPC G03F 7/038; G03F 7/168; G02B 1/04; C08F 20/30; C08F 20/32; G03F 7/0045

(57) ABSTRACT

A photosensitive resin composition, an optical film, and a method of producing an optical film are provided. The photosensitive resin composition includes an ethylenically unsaturated group-containing compound (A) having one or two aromatic rings; a bisphenol fluorene oligomer (B) having one or two (meth)acryloyl groups; and a photoinitiator (C), wherein the weight ratio of the ethylenically unsaturated group-containing compound (A) to the bisphenol fluorene oligomer (B) is from 0.50 to 0.95.

### CROSS-REFERENCE TO RELATED APPLICATION

This application claims the priority benefit of Taiwan application serial No. 108101438, filed on Jan. 15, 2019. The entirety of the above-mentioned patent application is hereby incorporated by reference herein and made a part of this specification.

### BACKGROUND

### 1. Technical Field

The disclosure relates to a resin composition, and in particular, to a photosensitive resin composition.

### 2. Description of Related Art

In recent years, the application of thick film photosensitive compositions has become increasingly wide. Touch mobile devices, fingerprint identification systems and wafer package all use the thick film photosensitive compositions. Most of general thick film photosensitive compositions are added with solvents, so it is difficult to achieve a thickness of about 20 to 120 μm on a substrate, and problems such as low penetration and high warpage likely occur under a high film thickness.

Particularly, the fingerprint identification system needs a thicker optical film to serve as a spacer because of its stricter optical requirement, and needs to have high penetration for both infrared rays and visible lights. However, in order to achieve the high penetration for both the infrared rays and the visible lights under the high film thickness (such as the thickness of 120 μm), there are many problems to be solved: for example, a thick film may cause substrate warpage; it is difficult to form a thick film due to the viscosity of a photosensitive resin solution; it is not easy to make the surface coating uniform; a photo-hardened optical film may crack; and the like.

Known from the above, how to provide a photosensitive resin composition having ideal optical properties and mechanical properties at a film thickness of 20 to 120 μm is actually a problem urgently needing to be solved by those skilled in the art.

### SUMMARY

In view of this, the disclosure provides various photosensitive resin composition having relatively low warpage and high penetration, an optical film and a method of producing an optical film.

The disclosure provides a photosensitive resin composition, including: an ethylenically unsaturated group-containing compound (A) having one or two aromatic rings; a bisphenol fluorene oligomer (B) having one or two (meth)acryloyl groups; and a photoinitiator (C), where a weight ratio of the ethylenically unsaturated group-containing compound (A) to the bisphenol fluorene oligomer (B) is 0.50 to 0.95.

In one embodiment of the disclosure, the photosensitive resin composition also includes a solvent (E). A content of the solvent (E) is equal to or less than 1% by weight of the photosensitive resin composition.

In one embodiment of the disclosure, the photosensitive resin composition contains no solvent.

In one embodiment of the disclosure, the ethylenically unsaturated group-containing compound (A) includes at least one of groups consisting of the following compounds represented by Formula (1) to Formula (14).

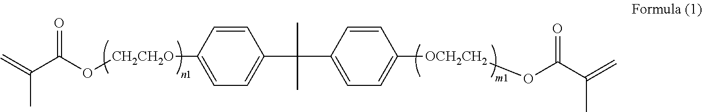

In Formula (1), n1 and m1 are each independently an integer of 0 to 20, and a sum of n1 and m1 is an integer of 1 to 20;

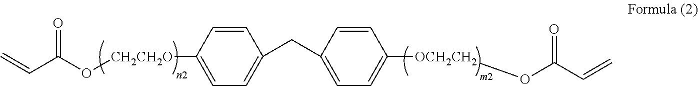

in Formula (2), n2 and m2 are each independently an integer of 0 to 4, and a sum of n2 and m2 is an integer of 2 to 4;

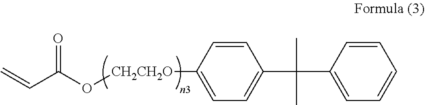

in Formula (3), n3 is an integer of 0 to 3;

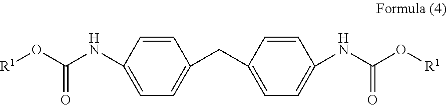

in Formula (4), R¹ is alkyl with a carbon number of 1 to 20;

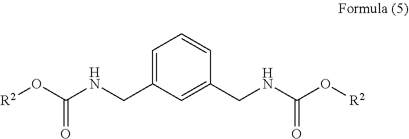

in Formula (5), R² is alkyl with a carbon number of 1 to 20;

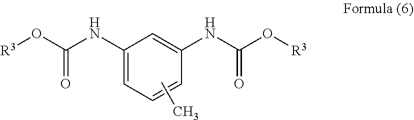

in Formula (6), R³ is alkyl with a carbon number of 1 to 20;

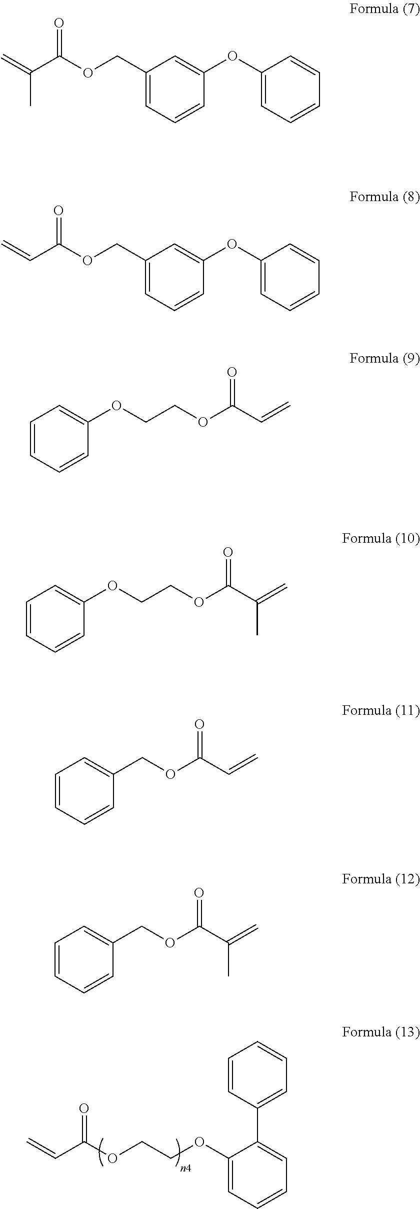

in Formula (13), n4 is an integer of 1 to 3; and

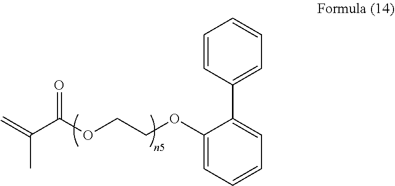

in Formula (14), n5 is an integer of 1 to 3.

In one embodiment of the disclosure, the ethylenically unsaturated group-containing compound (A) includes the compound represented by Formula (1).

In one embodiment of the disclosure, the weight-average molecular weight of the bisphenol fluorene oligomer (B) is 500 to 5000.

In one embodiment of the disclosure, the viscosity of the photosensitive resin composition is 600 to 7000 mPa·s at 25° C.

The disclosure further provides a variety of methods of producing an optical film, including the following steps: firstly, coating a substrate with the photosensitive resin composition to form a coated film; next, performing an exposure step to the coated film; and then, performing a baking step to the exposed coated film to form an optical film on the substrate.

In one embodiment of the disclosure, according to the method of producing the optical film, a wavelength of the exposure step is 200 to 500 nm.

In one embodiment of the disclosure, according to the method of producing the optical film, a temperature of the baking step is 130 to 280° C.

The disclosure further provides an optical film, which is produced by the method of producing an optical film.

In one embodiment of the disclosure, when the thickness of the optical film is 20 to 120 μm, penetration for a visible light with a wavelength of 380 to 780 nm is equal to or greater than 85%.

In one embodiment of the disclosure, when the thickness of the optical film is 20 to 120 μm, the penetration for an infrared ray with a wavelength of 780 to 1100 nm is equal to or greater than 90%.

In one embodiment of the disclosure, when the thickness of the optical film is 20 to 120 μm, a warpage of the optical film relative to the substrate is less than 0.25 mm.

Based on the above, when the weight ratio of the ethylenically unsaturated group-containing compound (A) to the bisphenol fluorene oligomer (B) of the photosensitive resin composition in one embodiment of the disclosure is 0.50 to 0.95, and when the photosensitive resin composition is applied to the optical film, the optical film may have relatively low warpage and high penetration, so as to improve the properties of substrate warpage and penetration which are caused by a thick film.

In order to make the aforementioned features and advantages of the disclosure comprehensible, embodiments accompanied with figures are described in detail below.

### DESCRIPTION OF THE EMBODIMENTS

### Definitions

Unless explicitly specified, wordings such as “including” and “having” should be generally understood to be open-ended and unrestricted.

Wordings in a singular form include plurality (vice versa) without specific descriptions. In addition, unless particularly specified, the wording “about” in front of a value generally includes the specific value. The wording “about” herein refers to a variation of a standard value +/−10% unless otherwise stated or implicated.

It should be understood that the order of the steps or the order in which certain actions are performed is not critical as long as the disclosure remains operatable. In addition, two or more steps or actions can be performed simultaneously.

Hereinafter, acrylic acid and/or methacrylic acid are/is represented by (meth)acrylic acid, and acrylate and/or methacrylate are/is represented by (meth)acrylate. Similarly, acryloyl group and/or methacryloyl group are/is represented by (meth)acryloyl group.

### <Photosensitive Resin Composition>

The disclosure provides a variety of photosensitive resin compositions. In one embodiment of the disclosure, the photosensitive resin composition includes an ethylenically unsaturated group-containing compound (A) having one or two aromatic rings; a bisphenol fluorene oligomer (B) having one or two (meth)acryloyl groups; and a photoinitiator (C). In addition, if necessary, the photosensitive resin composition may also include an additive (D), a solvent (E) or a combination thereof. Respective components of the photosensitive resin composition of the disclosure will be described in detail below.

### Ethylenically Unsaturated Group-Containing Compound (A)

The ethylenically unsaturated group-containing compound (A) has one or two aromatic rings. Since the aromatic ring is introduced into the ethylenically unsaturated group-containing compound (A), the warpage of an optical film formed by the photosensitive resin composition may be reduced. However, when there are more than two aromatic rings in the ethylenically unsaturated group-containing compound (A), the penetration of the optical film is reduced.

In addition, the ethylenically unsaturated group-containing compound (A) preferably has one or two (meth)acryloyl groups. Both the ethylenically unsaturated group-containing compound (A) and the bisphenol fluorene oligomer (B) which are used in one embodiment of the disclosure have the (meth)acryloyl groups, so that the reaction rate is consistent, and too fast partial hardening is not caused. Therefore, the penetration of the optical film may be maintained.

Specifically, the ethylenically unsaturated group-containing compound (A) includes at least one of groups consisting of the following compounds represented by Formula (1) to Formula (14).

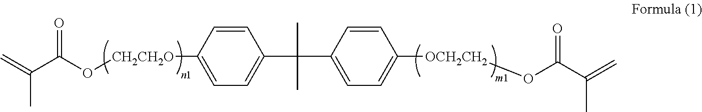

In Formula (1), n1 and m1 are each independently an integer of 0 to 20, and a sum of n1 and m1 is an integer of 1 to 20;

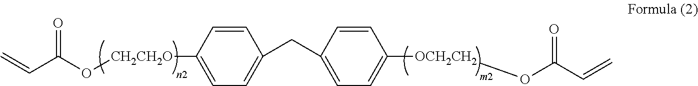

in Formula (2), n2 and m2 are each independently an integer of 0 to 4, and a sum of n2 and m2 is an integer of 2 to 4;

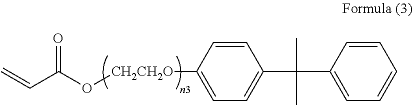

in Formula (3), n3 is an integer of 0 to 3;

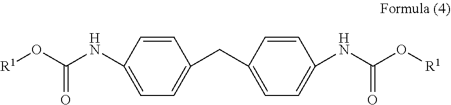

in Formula (4), R¹ is alkyl with a carbon number of 1 to 20;

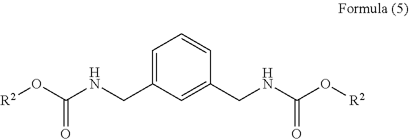

in Formula (5), R² is alkyl with a carbon number of 1 to 20;

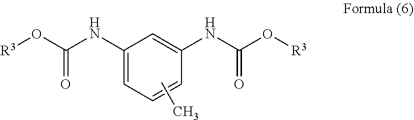

in Formula (6), R³ is alkyl with a carbon number of 1 to 20;

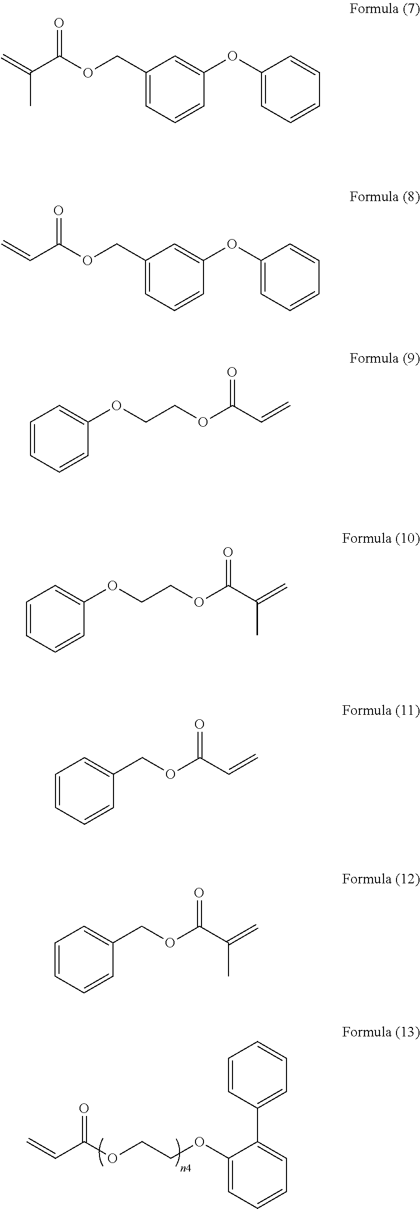

in Formula (13), n4 is an integer of 1 to 3; and

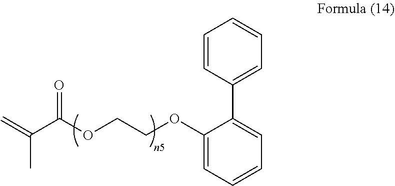

in Formula (14), n5 is an integer of 1 to 3.

A specific example of the compound represented by Formula (1) may be, for example, a compound represented by Formula (1-1).

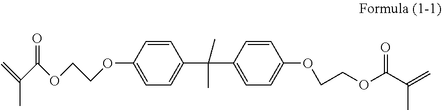 [SMILES: C=C(C)C(=O)OCCOc1ccc(C(C)(C)c2ccc(OCCOC(=O)C(=C)C)cc2)cc1]

A specific example of the compound represented by Formula (2) may be, for example, a compound represented by Formula (2-1).

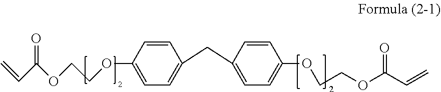

A specific example of the compound represented by Formula (3) may be, for example, a compound represented by Formula (3-1).

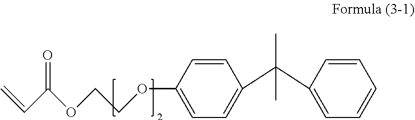

A specific example of the compound represented by Formula (4) may be, for example, a compound represented by Formula (4-1).

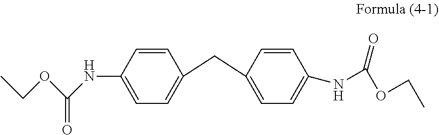 [SMILES: CCOC(=O)Nc1ccc(Cc2ccc(NC(=O)OCC)cc2)cc1]

A specific example of the compound represented by Formula (5) may be, for example, a compound represented by Formula (5-1).

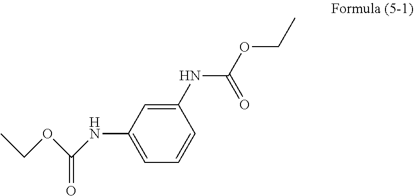 [SMILES: CCOC(=O)Nc1cccc(NC(=O)OCC)c1]

A specific example of the compound represented by Formula (6) may be, for example, a compound represented by Formula (6-1).

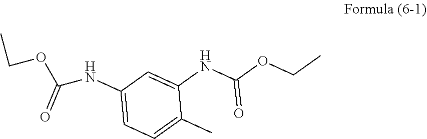 [SMILES: CCOC(=O)Nc1ccc(C)c(NC(=O)OCC)c1]

A specific example of the compound represented by Formula (13) may be, for example, a compound represented by Formula (13-1).

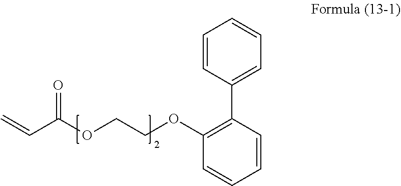

A specific example of the compound represented by Formula (14) may be, for example, a compound represented by Formula (14-1).

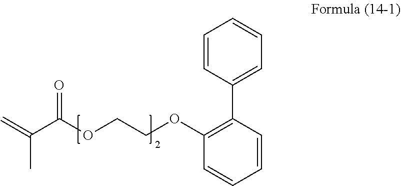

The ethylenically unsaturated group-containing compound (A) preferably includes the compound represented by Formula (1), more preferably the compound represented by Formula (1-1). By use of the compound represented by Formula (1), the penetration of the optical film may be further increased.

### Bisphenol Fluorene Oligomer (B)

The bisphenol fluorene oligomer (B) has one or two (meth)acryloyl groups. Both the ethylenically unsaturated group-containing compound (A) and the bisphenol fluorene oligomer (B) which are used in one embodiment have the (meth)acryloyl groups, so that the reaction rate is consistent, and too fast partial hardening is not caused. Therefore, the penetration of the optical film may be maintained.

The bisphenol fluorene oligomer (B) is not particularly limited, and may be, for example, MIRAMER HR6100 (modified bisphenol fluorene diacrylate) and MIRAMER HR6200 (modified bisphenol fluorene diacrylate) which are manufactured by Miwon Co., Ltd.

The weight ratio of the ethylenically unsaturated group-containing compound (A) to the bisphenol fluorene oligomer (B) may be 0.50 to 0.95, preferably 0.66 to 0.86. When the weight ratio of the ethylenically unsaturated group-containing compound (A) to the bisphenol fluorene oligomer (B) is in the above range, the optical film formed by the photosensitive resin composition may have relatively low warpage and high penetration.

The weight-average molecular weight of the bisphenol fluorene oligomer (B) may be 500 to 5000. When the weight-average molecular weight of the bisphenol fluorene oligomer (B) is in the above range, the viscosity of the photosensitive resin composition may be further made in an ideal range.

### Photoinitiator (C)

The photoinitiator (C) is not particularly limited, and may be, for example, an acetophenone compound, a phenyl ketone compound, a biimidazole compound, a benzophenone compound, an acyl oxime compound, an acylphosphine oxide, an α-diketone compound, an acyloin compound, an acyloinether compound, a quinone compound, a halogen compound, a peroxide, a cationic compound, or a combination thereof.

The acetophenone compound may be, for example, p-dimethylamino-acetophenone, α,α′-dimethoxyazoxy-acetophenone, 2,2′-dimethyl-2-phenyl-acetophenone, p-methoxy-acetophenone, 2-methyl-1-(4-methylthiophenyl)-2-morpholino-1-propanone, 2-benzyl-2-N,N-dimethylamino-1-(4-morpholinophenyl)-1-butanone), or a combination thereof.

The phenyl ketone compound may be, for example, 1-hydroxycyclohexyl-phenyl-ketone (trade name: Irgacure 184, manufactured by Ciba Specialty Chemicals Co., Ltd.), 2-hydroxy-2-methyl-1-phenyl-propane-1-one (trade name: DAROCUR 1173, manufactured by Ciba Specialty Chemicals Co., Ltd.), 2-hydroxy-1-{4-[4-(2-hydroxy-2-methyl-propionyl)benzyl]phenyl}-2-methyl-propane-1-one (trade name: IRGACURE 127, manufactured by Ciba Specialty Chemicals Co., Ltd.), or a combination thereof.

The biimidazole compound may be, for example, 2,2′-bis(o-chlorophenyl)-4,4′,5,5′-tetraphenyl-biimidazole, 2,2′-bis(o-fluorophenyl)-4,4′,5,5′-tetraphenyl-biimidazole, 2,2′-bis(o-methyl phenyl)-4,4′,5,5′-tetraphenyl-biimidazole, 2,2′-bis(o-methoxyphenyl)-4,4′,5,5′-tetraphenyl-biimidazole, 2,2′-bis(o-ethylphenyl)-4,4′,5,5′-tetraphenyl-biimidazole, 2,2′-bis(p-methoxyphenyl)-4,4′,5,5′-tetraphenyl-biimidazole, 2,2′-bis(2,2′,4,4′-tetramethoxyphenyl)-4,4′,5,5′-tetraphenyl-biimidazole, 2,2′-bis(2-chlorophenyl)-4,4′,5,5′-tetraphenyl-biimidazole, 2,2′-bis(2,4-dichlorophenyl)-4,4′,5,5′-tetraphenyl-biimidazole, or a combination thereof.

The benzophenone compound may be, for example, thioxanthone, 2,4-diethylthioxanthanone, thioxanthone-4-sulfone, benzophenone 4,4′-bis(dimethylamino)benzophone, 4,4′-bis(diethylamino)benzophenone, or a combination thereof.

The acyl oxime compound may be, for example, ethanone,1-[9-ethyl-6-(2-methylbenzoyl)-9H-carbazole-3-yl]-,1-(O-acetyl oxime (such as a product “CGI-242” manufactured by Ciba Specialty Chemicals Co., Ltd.), 1-(4-phenyl-thio-phenyl)-octane-1,2-dione 2-oxime-O-benzoate (such as a product product “CGI-124” manufactured by Ciba Specialty Chemicals Co., Ltd.), ethanone,1-[9-ethyl-6-(2-cholro-4-benzyl-thio-benzoyl)-9H-carbazole-3-yl]-,1-(O-acetyl oxime manufactured by Asahi Denka Co., Ltd., or a combination thereof.

The acylphosphineoxide may be, for example, 2,4,6-trimethyl-benzoyldiphenyl phosphineoxide, bis-(2,6-dimethoxy-benzoyl)-2,4,4-trimethylbenzyl phosphineoxide, phenylbis(2,4,6-trimethylbenzoyl)phosphine oxide, or a combination thereof.

The α-diketone compound may be, for example, benzil, acetyl, or a combination thereof.

The acyloin compound may be, for example, benzoin.

The acyloinether compound may be, for example, benzoin methylether, benzoinethylether, benzoin isopropyl ether, or a combination thereof.

The quinone compound may be, for example, anthraquinone, 1,4-naphthoquinone, or a combination thereof.

The halogen compound may be, for example, phenacyl chloride, tribromomethyl phenylsulfone, or tris(trichloromethyl)-s-triazine, or a combination thereof.

The peroxide may be, for example, di-tert-butylperoxide.

The cationic compound may be, for example, diazonium salt, iodonium salt, sulfonium salt, or a combination thereof.

The photoinitiator (C) is preferably 2-methyl-1-(4-methylthiophenyl)-2-morpholino-1-propanone, 2-benzyl-2-N,N-dimethylamino-1-(4-morpholinophenyl)-1-butanone, 2,4,6-trimethyl-benzoyldiphenyl phosphineoxide, phenylbis(2,4,6-trimethylbenzoyl)phosphine oxide, or a combination thereof.

Based on 100 parts by weight of the ethylenically unsaturated group-containing compound (A), the photoinitiator (C) may account for 0.05 to 40 parts by weight, preferably 0.1 to 20 parts by weight, more preferably 0.5 to 10 parts by weight. When the photoinitiator (C) is in the above range, the reactivity of the initiator may be sufficiently exerted.

### Additive (D)

The photosensitive resin composition in one embodiment may be further selectively added with an additive (D) on the premise of not affecting the effect of the disclosure. The additive (D) is not particularly limited. Specifically, the additive (D) includes a fluorine surfactant, a siloxane surfactant, a nonionic surfactant, a leveling agent, or a combination thereof.

Based on 100 parts by weight of the ethylenically unsaturated group-containing compound (A), the additive (D) may account for 0.005 to 0.015 part by weight.

### Solvent (E)

The photosensitive resin composition preferably contains no solvent. However, the photosensitive resin composition in one embodiment may be further selectively added with a solvent (E) on the premise of not affecting the effect of the disclosure. The solvent (E) is a solvent that may dissolve the ethylenically unsaturated group-containing compound (A), the bisphenol fluorene oligomer (B), the photoinitiator (C) and the additive (D), but does not react with the above components.

The solvent (E) is not particularly limited, and may be, for example, ethylene glycol monoalkyl ethers, ethylene glycol dialkyl ethers, ethylene glycol monoalkyl ether acetates, propylene glycol monoalkyl ethers, propylene glycol dialkyl ethers, propylene glycol monoalkyl ether acetates, diethylene glycol dialkyl ethers (such as diethylene glycol diethyl ether and diethylene glycol methyl ethyl ether), diethylene glycol monoalkyl ether acetates, dipropylene glycol monoalkyl ethers, dipropylene glycol dialkyl ethers, dipropylene glycol monoalkyl ether acetates, esters, ketones, amides, lactones, and the like. Specific examples of the preferred solvent may be, for example, propylene glycol monomethyl ether acetate, diethylene glycol ethyl methyl ether, γ-butyrolactone, N-methyl pyrrolidone, 1,3-butylene glycol diacetate, or a combination thereof.

The content of the solvent (E) is equal to or less than 1% by weight of the photosensitive resin composition. When the content of the solvent (E) exceeds 1% by weight of the photosensitive resin composition, and when the photosensitive resin composition is to form a coating layer of a thick film (thickness: equal to or greater than 50 μm), the solvent volatilizes and easily generates bubbles in the coated film. In addition, the photosensitive resin composition more preferably contains no solvent.

### <Method of Preparing a Photosensitive Resin Composition>

A method for preparing a photosensitive resin composition is not particularly limited. For example, the method includes that: an ethylenically unsaturated group-containing compound (A), a bisphenol fluorene oligomer (B) and a photoinitiator (C) are placed in a stirrer and stirred, so as to be uniformly mixed into a solution state; and if necessary, an additive (D), a solvent (E) or a combination thereof may be added and then uniformly mixed to obtain a liquid photosensitive resin composition.

The viscosity of the photosensitive resin composition in one embodiment is preferably 600 to 7000 mPa·s at 25° C.

### <Method of Producing an Optical Film>

In one embodiment of the disclosure provides a method of producing an optical film, including the steps that: firstly, coating a substrate with the photosensitive resin composition to form a coated film; next, performing an exposure step to the coated film; and then, performing a baking step to the exposed coated film to form an optical film on the substrate.

A method of coating the substrate with the photosensitive resin composition may be implemented by a spin coater, a spin-less coating machine, or a slit-die coating machine. The spin coater is preferred. In case of using the spin coater, a rotating speed is 800 to 3500 rpm, and the thickness of the formed coated film is 20 to 120 μm.

The substrate may be, for example, a glass substrate, a sapphire substrate or a silicon wafer substrate.

A light source of the exposure step may be ultraviolet rays such as g-line, h-line, or i-line. In addition, a device for the exposure step is not particularly limited, and may be, for example, a high mercury lamp, a super high mercury lamp, or a metal halide lamp. The wavelength in the exposure step may be 200 to 500 nm.

A temperature of the baking step may be from 130 to 280° C.

When the thickness of the optical film is 20 to 120 μm, the penetration for a visible light with a wavelength of 380 to 780 nm is equal to or greater than 85%, and the penetration for an infrared ray with a wavelength of 780 to 1100 nm is equal to or greater than 90%. In addition, when the thickness of the optical film is 20 to 120 μm, the warpage of the optical film relative to the substrate is less than 0.25 mm.

The disclosure will be further described in the following examples, but it should be understood that the examples are merely illustrative and are not to be construed as limiting the implementations of the disclosure.

### EXAMPLES OF A PHOTOSENSITIVE RESIN COMPOSITION AND AN OPTICAL FILM

Examples 1 to 3 and comparative examples 1 and 2 of the photosensitive resin composition and the optical film are described below.

### Example 1

a. Photosensitive Resin Composition

38.80% by weight of an ethylenically unsaturated group-containing compound (A), 58.20% by weight of a bisphenol fluorene oligomer (B) and 3% by weight of 2-methyl-1-(4-methylthiophenyl)-2-morpholino-1-propanone (manufactured by BASF Japan Co., Ltd., IRGACURE 907) were mixed and then were stirred uniformly with a stirrer to prepare the photosensitive resin composition of Example 1.

b. Optical Film

A silicon wafer substrate was coated with the various photosensitive resin compositions prepared in the Example by a spin coating method (a spin coater with the model of MK-VIII, manufactured by Tokyo Electron Limited (TEL), with a rotating speed of 1000 rpm). Next, exposure was performed using an ultraviolet light at 1600 J/m² (an exposure machine with the model of 5500 iZa, manufactured by Canon Co., Ltd.) to form a semi-finished product. Then, baking was performed at 220° C. for 20 minutes to obtain the optical film. The obtained semi-finished product and optical film were evaluated in the following evaluation methods, and the results were shown in Table 1.

### Examples 2 to 3 and Comparative Examples 1 to 2

The photosensitive resin compositions of Examples 2 to 3 and the comparative examples 1 to 2 were prepared by the same steps as in Example 1, and differences were that: the component types of the photosensitive resin composition and usage amounts thereof were changed (as shown in Table 1). The obtained photosensitive resin compositions were evaluated in the following evaluation methods, and the results were shown in Table 1.

TABLE 1

| | | | | | Comparative | Comparative |
|---|---|---|---|---|---|---|
| | | Example 1 | Example 2 | Example 3 | example 1 | example 2 |
| Ethylenically | Compound | 38.80 | 33.95 | 44.62 | 76.63 | 40.74 |
| unsaturated | represented by | | | | | |
| group-containing | Formula (1) | | | | | |
| compound (A) | (BPA3EODA, | | | | | |
| (wt %) | purchased from | | | | | |
| | CHEMBRIDGE) | | | | | |
| Bisphenol | MIRAMER | 58.20 | 63.05 | 52.38 | 20.37 | — |
| fluorene | HR6100 | | | | | |
| oligomer (B) | | | | | | |
| (wt %) | | | | | | |
| Epoxy acrylic | Bisphenol A | — | — | — | — | 56.26 |
| oligomer (B′) | epoxy diacrylate | | | | | |
| (wt %) | (CN104 | | | | | |
| | manufactured by | | | | | |
| | Arkema) | | | | | |
| Sum of ethylenically unsaturated | | 97 | 97 | 97 | 97 | — |
| group-containing compound (A) | | | | | | |
| and bisphenol fluorene oligomer | | | | | | |
| (B) (wt %) | | | | | | |
| A:B (weight ratio) | | 40:60 | 35:65 | 46:54 | 79:21 | — |
| A/B (weight ratio) | | 0.667 | 0.538 | 0.851 | 3.762 | — |
| Sum of ethylenically unsaturated | | — | — | — | — | 97 |
| group-containing compound (A) | | | | | | |
| and epoxy acrylic oligomer (B′) | | | | | | |
| (wt %) | | | | | | |
| A:B′ (weight ratio) | | — | — | — | — | 42:58 |
| A/B′ (weight ratio) | | — | — | — | — | 0.724 |
| Photoinitiator | IRGACURE 907 | 3.00 | 3.00 | 3.00 | 3.00 | 3.00 |
| (C) (wt %) | | | | | | |
| Evaluation | Film thickness | ⊚ | ⊚ | ⊚ | X | ⊚ |
| result | Warpage | ⊚ | ⊚ | ⊚ | Δ | X |
| | Penetration for | ⊚ | ⊚ | ⊚ | ⊚ | Δ |
| | visible light | | | | | |
| | Penetration for | ⊚ | ⊚ | ⊚ | ⊚ | Δ |
| | infrared ray | | | | | |
| | Recoatability | ⊚ | ⊚ | ⊚ | ⊚ | ⊚ |

### <Evaluation Method>

a. Film Thickness

The film thickness of the semi-finished product of the optical film was measured with an optical film thickness meter (Model: VM-1210, manufactured by Dainippon Seiki Co., Ltd.).

⊚: the film thickness is between 20 μm and 120 μm; [symbol]
: the film thickness is less than 20 μm.
b. Warpage

A thickness gauge (Model: 25410015, manufactured by Phoenix Electronics Co., Ltd., Germany) was inserted into the edge of the substrate, and the thickness of a gap between the edge of the substrate and a plane was measured as the warpage. The warpage was evaluated in the following way.

⊚: warpage is less than 0.25 mm;
Δ: warpage is equal to or greater than 0.25 mm and less than 0.3 mm; [symbol]
: warpage is greater than 0.3 mm.
c. Penetration for Visible Light

The penetration of the optical film at the wavelength of 380 to 780 nm was measured with an ultraviolet-visible spectrophotometer (Model: U2900, manufactured by HITACHI Co., Ltd.).

⊚: penetration is equal to or greater than 85%;
Δ: penetration is equal to or greater than 80% and less than 85%; [symbol]
: penetration is less than 80%.
d. Penetration for Infrared Ray

The penetration of the optical film at the wavelength of 780 to 1100 nm was measured with an ultraviolet-visible spectrophotometer (Model: U2900, manufactured by HITACHI Co., Ltd.).

⊚: penetration is equal to or greater than 98%;
Δ: penetration is equal to or greater than 80% and less than 98%; [symbol]
: penetration is less than 80%.
e. Recoatability

The dyne pen of America ACCU Company was used to brush ink marks of about 100 mm on the optical film to observe whether the ink marks in an amount equal to or greater than 90% shrink in 2 seconds and form ink drops, and when no shrinkage is caused, a dyne number of the dyne pen reflects the dyne number of the optical film.

⊚: surface tension is equal to or greater than 38 dyne/cm; [symbol]
: surface tension is less than 38 dyne/cm.

### <Evaluation Result>

It can be seen from Table 1 that the photosensitive resin compositions (Examples 1 to 3) which use the bisphenol fluorene oligomer (B) and have the weight ratios of the ethylenically unsaturated group-containing compound (A) to the bisphenol fluorene oligomer (B) of 0.50 to 0.95 have good recoatability. In addition, a film having the film thickness between 20 μm and 120 μm may be formed, and the formed optical film has low warpage and high penetration for visible lights and infrared rays.

In contrast, the photosensitive resin composition (the comparative example 1) having the weight ratio of the ethylenically unsaturated group-containing compound (A) to the bisphenol fluorene oligomer (B) of greater than 0.95 is unable to form a film having the film thickness between 20 μm and 120 μm, and the formed optical film has high warpage.

In addition, the optical film formed by the photosensitive resin composition (the comparative example 2) prepared by substituting the bisphenol fluorene oligomer (B) by the epoxy acrylic oligomer (B′) has high warpage and low penetration for visible lights and infrared rays.

Based on the above, the photosensitive resin composition in one embodiment contains the ethylenically unsaturated group-containing compound and the specific bisphenol fluorene oligomer. When the weight ratio of the ethylenically unsaturated group-containing compound to the bisphenol fluorene oligomer is 0.50 to 0.95, the optical film formed by the photosensitive resin composition has relatively low warpage and high penetration, so as to improve the properties of substrate warpage and penetration which are caused by a thick film.

Although the disclosure has been disclosed as above with the embodiments, but the embodiments are not intended to limit the disclosure. Any one of ordinary skill in the art can make some changes and refinements without departing from the spirit and scope of the disclosure. Therefore, the protection scope of the disclosure shall be defined by the scope of the appended claims.

What is claimed is:

1. A photosensitive resin composition, comprising:
an ethylenically unsaturated group-containing compound (A), comprising one or two aromatic rings;
a bisphenol fluorene oligomer (B), comprising one or two (meth)acryloyl groups; and
a photoinitiator (C),
wherein a weight ratio of the ethylenically unsaturated group-containing compound (A) to the bisphenol fluorene oligomer (B) is 0.50 to 0.95.

2. The photosensitive resin composition according to claim 1, further comprising: a solvent (E), wherein a content of the solvent (E) is equal to or less than 1% by weight of the photosensitive resin composition.

3. The photosensitive resin composition according to claim 1, wherein the photosensitive resin composition contains no solvent.

4. The photosensitive resin composition according to claim 1, wherein the ethylenically unsaturated group-containing compound (A) comprises at least one of groups consisting of the following compounds represented by Formula (1) to Formula (14): 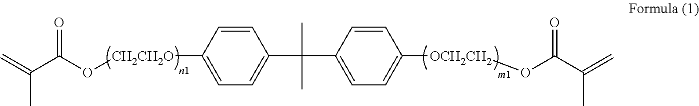
in Formula (1), n1 and m1 are each independently an integer of 0 to 20, and a sum of n1 and m1 is an integer of 1 to 20; 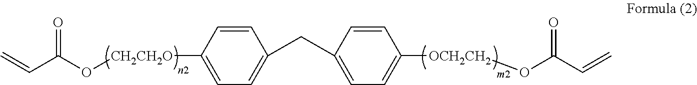
in Formula (2), n2 and m2 are each independently an integer of 0 to 4, and a sum of n2 and m2 is an integer of 2 to 4; 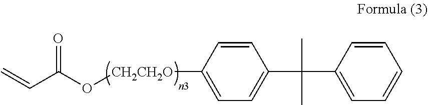
in Formula (3), n3 is an integer of 0 to 3; 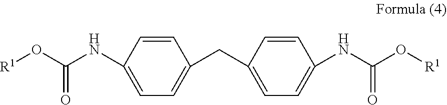
in Formula (4), R¹ is alkyl with a carbon number of 1 to 20; 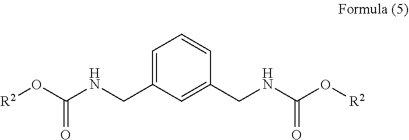
in Formula (5), R² is alkyl with a carbon number of 1 to 20; 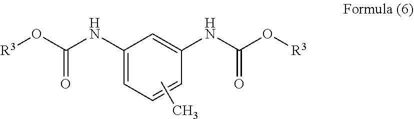
in Formula (6), R³ is alkyl with a carbon number of 1 to 20; 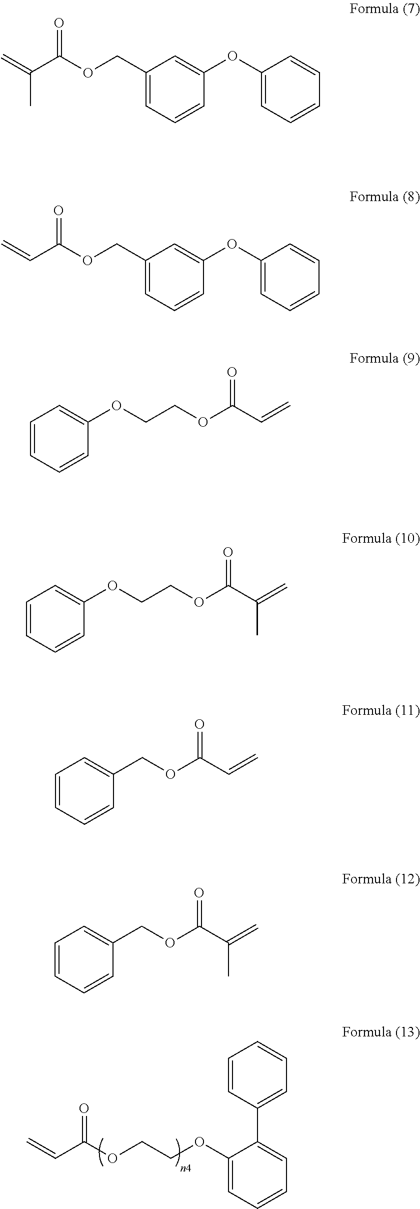
in Formula (13), n4 is an integer of 1 to 3; and 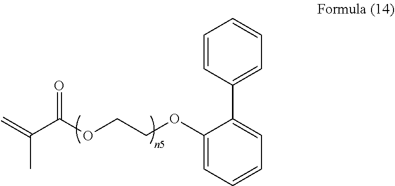
in Formula (14), n5 is an integer of 1 to 3.

5. The photosensitive resin composition according to claim 4, wherein the ethylenically unsaturated group-containing compound (A) comprises the compound represented by Formula (1).

6. The photosensitive resin composition according to claim 1, wherein the weight-average molecular weight of the bisphenol fluorene oligomer (B) is 500 to 5000.

7. The photosensitive resin composition according to claim 1, wherein the viscosity of the photosensitive resin composition is 600 to 7000 mPa·s at 25° C.

8. A method of producing an optical film, comprising:
coating a substrate with the photosensitive resin composition according to claim 1 to form a coated film;
performing an exposure step to the coated film; and
performing a baking step to the exposed coated film to form an optical film on the substrate.

9. The method of producing the optical film according to claim 8, wherein a wavelength of the exposure step is 200 to 500 nm.

10. The method of producing the optical film according to claim 8, wherein a temperature of the baking step is 130 to 280° C.

11. An optical film, which is produced by the method of producing an optical film according to claim 8.

12. The optical film according to claim 11, wherein when the thickness of the optical film is 20 to 120 μm, penetration for a visible light with a wavelength of 380 to 780 nm is equal to or greater than 85%.

13. The optical film according to claim 11, wherein when the thickness of the optical film is 20 to 120 μm, penetration for an infrared ray with a wavelength of 780 to 1100 nm is equal to or greater than 90%.

14. The optical film according to claim 11, wherein when the thickness of the optical film is 20 to 120 μm, a warpage of the optical film relative to the substrate is less than 0.25 mm.
